(19) United States
(12) Patent Application Publication
(10) Pub. No.: US 2014/0352751 A1
(43) Pub. Date: Dec. 4, 2014

(54) SOLAR CELL OR TANDEM SOLAR CELL AND METHOD OF FORMING SAME

(71) Applicant: TSMC Solar Ltd., Taichung City (TW)

(72) Inventors: Chung-Hsien WU, Luzhu Township (TW); Wei-Lun XU, Taipei City (TW); Shih-Wei CHEN, Kaohsiung City (TW); Wen-Tsai YEN, Caotun Township (TW); Li XU, Taichung City (TW)

(21) Appl. No.: 13/906,932

(22) Filed: May 31, 2013

(51) Int. Cl. H01L 31/0725; H01L 31/18

(52) U.S. Cl. CPC H01L 31/0725; H01L 31/1892
USPC 136/244; 136/256; 438/98

(57) ABSTRACT

A solar cell includes an absorber layer, a buffer layer on the absorber layer, a front contact layer where a glass substrate, a back contact layer on the glass substrate, the absorber layer on the back contact layer, the buffer layer, and the front contact layer are manufactured as a first module at a temperature exceeding 500 degrees Celsius. The solar further includes an extracted portion from the first module where the extracted portion includes the absorber layer, the buffer layer, and the front contact layer, and where the extracted portion is applied to a flexible substrate or other substrate.

### FIELD

This disclosure relates to photovoltaic solar cells and methods of fabricating the same.

### BACKGROUND

Solar cells are photovoltaic components for direct generation of electrical current from sunlight. Due to the growing demand for clean sources of energy, the manufacture of solar cells has expanded dramatically in recent years and continues to expand. Various types of solar cells exist and continue to be developed. Solar cells include absorber layers that absorb the sunlight that is converted into electrical current.

A variety of solar energy collecting modules currently exists. The solar energy collecting modules generally include large, flat substrates and include a back contact layer, an absorber layer, a buffer layer and a front contact layer, which can be a transparent conductive oxide (TCO) material. A plurality of solar cells are formed on one substrate, and are connected in series by respective interconnect structures in each solar cell to form a solar cell module.

Each interconnect structure comprises three scribe lines, referred to as P1, P2 and P3. The P1 scribe line extends through the back contact layer and is filled with the absorber material. The P2 scribe line extends through the buffer layer and the absorber layer and is filled with the (conductive) front contact material. Thus, the P2 scribe line connects the front electrode of a first solar cell to the back electrode of an adjacent solar cell. The P3 scribe line extends through the front contact, buffer and absorber layers.

The portion of the solar cell outside of the interconnect structure is referred to as the active cell, because the interconnect structure does not contribute to the solar energy absorption and generation of electricity. The series resistance of the solar cell module is thus largely dependent on the resistance of the front contact layer and the contact resistance between the front and back contact.

### BRIEF DESCRIPTION OF THE DRAWINGS

FIG. 1 is a series of cross section views of an embodiment of various stages of manufacture of a solar cell or a tandem solar cell described herein.

FIG. 2 is another series of cross section views of a variation of the solar cell or tandem solar cell of FIG. 1, where transparent conductive tape is used instead of transparent tap.

FIG. 3 is a another series of cross section views and one top plan view of a variation of the solar cell of FIG. 1.

FIG. 4 is a cross section of another solar cell variation of FIG. 3.

FIG. 5 is a flow chart of a method of making a solar cell as shown and described herein.

### DETAILED DESCRIPTION

This description of the exemplary embodiments is intended to be read in connection with the accompanying drawings, which are to be considered part of the entire written description. The drawings are not drawn to scale. In the various drawings, like reference numerals indicate like items, unless expressly indicated otherwise in the text.

In the description, relative terms such as “lower,” “upper,” “horizontal,” “vertical,”, “above,” “below,” “up,” “down,” “top” and “bottom” as well as derivative thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation. Terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

Solar cells can be made of both rigid and flexible materials. High efficiency solar cell are typically prepared at high temperatures exceeding 500 degrees Celsius. However, temperatures exceeding 500 degrees Celsius are too high for polymer substrates to prepare flexible solar cells with high efficiency. The most promising flexible substrates are polyimide (PI) and metal foil. The maximum applicable temperature of PI is typically below 500 degrees Celsius which leads to lower efficiency.

High process temperatures causes diffusion of impurities (such as Fe, Cr or Ni) from metal foils (Ti, stainless, etc.) to decrease the device efficiency. Furthermore, using flexible substrates typically requires at least an additional sodium source for proper processing. In the context of tandem solar cells, high process temperatures can destroy the bottom cell of the tandem structure solar cells.

The front contact (TCO) layer of a solar cell performs a conductive function, while being light transparent. The TCO layer typically forms above a buffer layer and the buffer layer form above an absorber layer that absorbs light or light energy. The absorber layer forms above a back contact layer (such as molybdenum or Mo) and the back contact layer forms on a substrate. In one embodiment, Chalcopyrite (CIGS containing copper, indium, gallium and selenium) solar cells are prepared on rigid substrate first such as on a soda lime glass (SLG) substrate. The embodiments herein involve separating or extracting an extracted portion. The extracted portion can be separated from the back contact layer and substrate by tearing-up or delaminating the chalcopyrite thin film, buffer layer, and TCO from the substrate and back contact layer (Mo) by using tape or any other organic glue. The separation process occurs at room temperature or alternatively there can be an application of heat, electricity or pressure to assist with the separation (and then with any subsequent lamination or adhering process). The process continues by transferring, adhering, applying or pasting the extracted portion (chalcopyrite thin film/buffer layer/TCO) to another substrate. This new substrate can be another kind of material used for buildings or metal foil or flexible substrate coatings with conductive metal. Between the transfer films or the extracted portion and the substrate a conductive polymer can be added to decrease the contact resistance and improve the adhesion between layers. Alternatively, the extracted portion can be coupled to another solar cell to form a tandem solar cell structure.

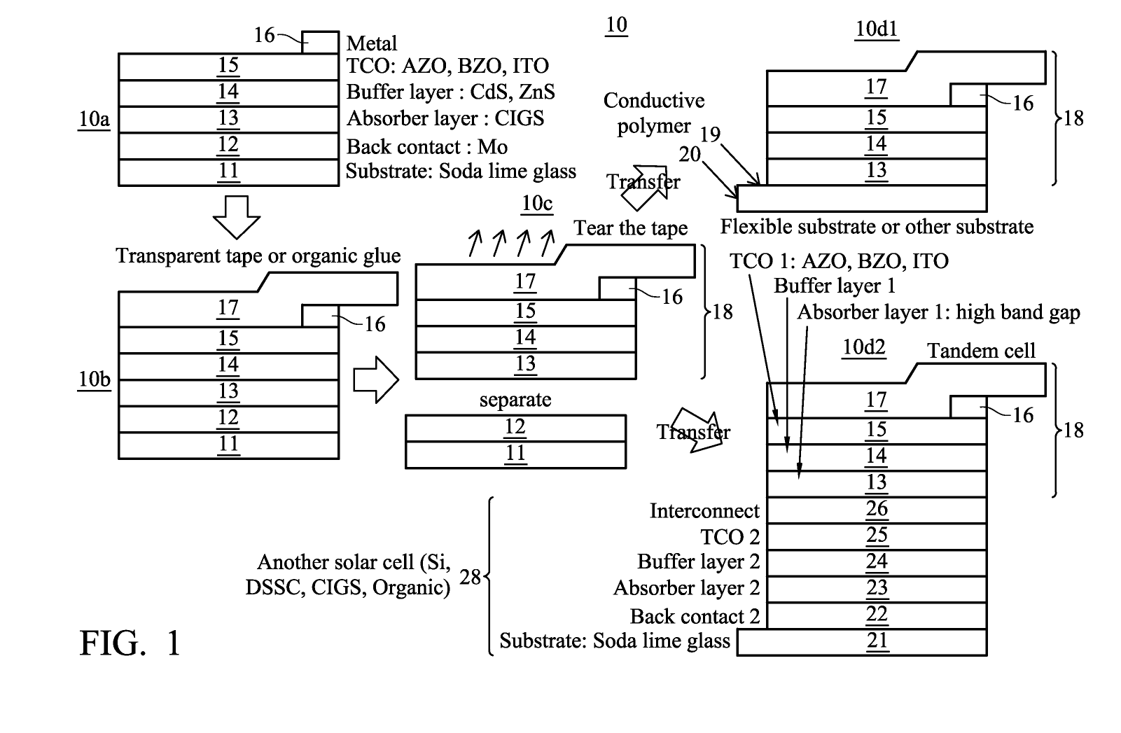

Thus, in one particular embodiment as illustrated in the process 10 of FIG. 1, chalcopyrite (Copper, Indium, Gallium, Selenium or CIGS) solar cells are prepared on a rigid substrate 11 first. The rigid substrate can be soda lime glass (SLG) for example. In a first subset 10a of the process 10, a back contact layer 12 such as molybdenum is applied or place above the rigid substrate 11. An absorber layer 13 such as CIGS is applied or placed above the back contact layer 12. A buffer layer 14 such as cadmium sulfide or zinc sulfide is applied or place above the absorber layer 13. Then, a transparent conductive oxide (TCO) layer 15 is applied or placed above the buffer layer 14. A metal bar 16 such as a bus bar can be applied or place on the TCO layer 15.

At a second subset 10b of the process 10, a transparent tape or organic glue 17 is applied or placed on the TCO layer 15 and the metal bar 16 as shown. At a third subset 10c of the process 10, an extracted portion 18 including the tape or glue 17, the metal bar 16, the TCO layer 15, the buffer layer 14, and the absorber layer 13 is extracted from, separate from, or delaminated from, or torn away from the back contact layer 12 and the substrate 11. In other words, in one particular embodiment, the process 10c involves delaminating the chalcopyrite thin film/buffer layer/TCO layer (13, 14, 15, 16) from the substrate/Mo (11, 12) using tape or any other organic glue 17. The process of 10c is done at room temperatures without necessarily applying temperatures exceeding 500 degrees Celsius. If needed, some application of heat, electricity or pressure can be used in the separation or delamination process of 10c.

In one alternative transfer process 10d1, the extracted portion 18 is then transferred or pasted to another substrate such as a flexible substrate 20 which can optionally include a metal foil or conductive polymer layer 19. Between the transfer films or extracted portion 18 and the substrate 20, the addition of a conductive polymer layer is used decrease the contact resistance and improve the adhesion between extracted portion 18 and the substrate 20. The substrate 20 can be made of other kinds of materials and can include metal foil or other flexible substrate coatings with conductive metal. Alternatively, as shown in the alternative transfer process 10d2, the extracted portion 18 can be coupled to another solar cell 28 to form the tandem structure shown. The other solar cell 28 includes a second TCO layer 25, a second buffer layer 24, a second absorber layer 23, a second back contact layer 22, and a substrate 2. The solar cell 28 is shown as an example and is not limited to the particular structure shown. The extracted portion 18 and the other solar cell 28 can be coupled together via an interconnect layer 26. The interconnect layer 26 can be made of can be made of clear materials such as clear polyimide or other clear plastics or P+ type semiconductors such as ZnTe:Cu, CuxSe2, CuInO2:Ca or BaCu2S2. The band gap of these P+ type semiconductors should be equal or greater than the top cell to avoid optical losses.

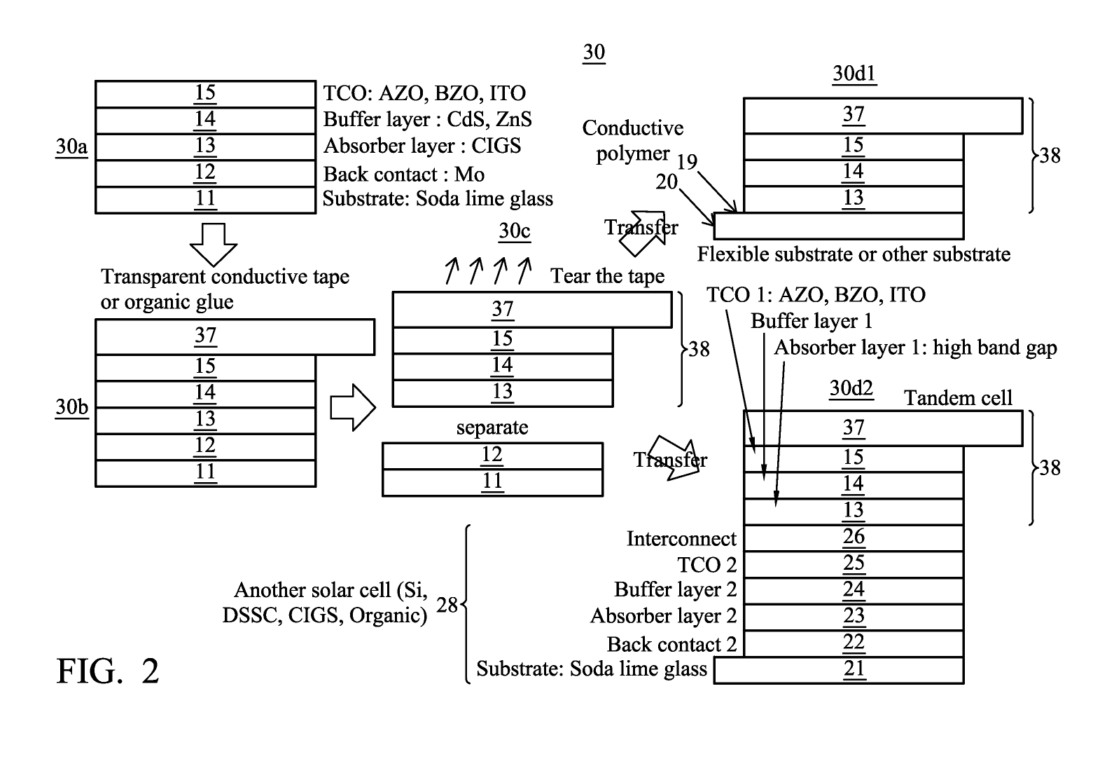

FIG. 2 illustrates another embodiment of a process 30 that is similar to the process 10 of FIG. 1 except that a transparent conductive tape or conductive glue 37 is used instead of the transparent tape 17 of FIG. 1. As before, CIGS solar cells are prepared on a rigid substrate 11 first. The rigid substrate can be SLG for example. In a first subset 30a of the process 30, the back contact layer 12 (Mo) is applied or placed above the rigid substrate 11. The absorber layer 13 (CIGS) is applied or placed above the back contact layer 12. A buffer layer 14 is applied or placed above the absorber layer 13. Then, the TCO layer 15 is applied or placed above the buffer layer 14. Instead of a metal bar 16, transparent conductive tape 37 can be used and placed on the TCO layer 15 as further detailed below with respect to 30b.

At a second subset 30b of the process 30, the transparent tape or organic glue 17 is applied or placed on the TCO layer 15 as shown. At a third subset 30c of the process 30, an extracted portion 38 including the conductive tape or glue 37, the TCO layer 15, the buffer layer 14, and the absorber layer 13 is extracted from, separate from, or delaminated from, or torn away from the back contact layer 12 and the substrate 11. In other words, in one particular embodiment, the process 30c involves delaminating the chalcopyrite thin film/buffer layer/TCO layer (13, 14, 15, 16) from the substrate/Mo (11, 12) using conductive tape or any other conductive glue 37. The process of 30c is done at room temperatures without necessarily applying temperatures exceeding 500 degrees Celsius. If needed, some application of heat, electricity or pressure can be used in the separation or delamination process of 30c.

In one alternative transfer process 30d1, the extracted portion 38 is then transferred or pasted to another substrate such as a flexible substrate 20 which can optionally include a metal foil or conductive polymer layer 19. The substrate 20 can be made of other kinds of materials and can include metal foil or other flexible substrate coatings with conductive metal. Alternatively, as shown in the alternative transfer process 30d2, the extracted portion 38 can be coupled to another solar cell 28 to form the tandem structure shown. The solar cell 28 is shown as an example and is not limited to the particular structure shown. The extracted portion 38 and the other solar cell 28 can be coupled together via an interconnect layer 26. One of the most promising thin film solar cells is the polycrystalline chalcopyrite Cu(In,Ga)Se2 (again, referred to as CIGS). The efficiency of the CIGS solar cell can be up to 20.3% on rigid glass substrates such as soda lime glass where the process temperature is higher than 550 degrees Celsius. Flexible solar cells are highly attractive due to its wide variety of applications such as in mobile communications, Building Integrated Photovoltaics (BIPV) or consumer electronic products. Flexible chalcopyrite solar cells are direct deposited on flexible substrates by a number of methods including the co-evaporation method, sputtering/SAS process, electro-deposition method or printing method. Sodium from SLG can enhance the device performance. However, there are no sodium ions in flexible substrates as opposed to SLG. An additional sodium source is usually added by depositing NaF, Na:Mo or Na:CuGa. With respect to tandem solar cells, such tandem solar cells can achieve higher efficiency. However, the absorber layer band gap of a top cell in a tandem cell is higher than the bottom cell of a tandem cell to convert light to electron and electron-hole pair effectively. The deposition sequence is from the bottom to the top. Hence the process temperature for the top cell is limiting using the usual process, but using the processes described herein eliminates the concern of damaging the bottom cell due to heat processing of the top cell since the top cell is primarily processed separately.

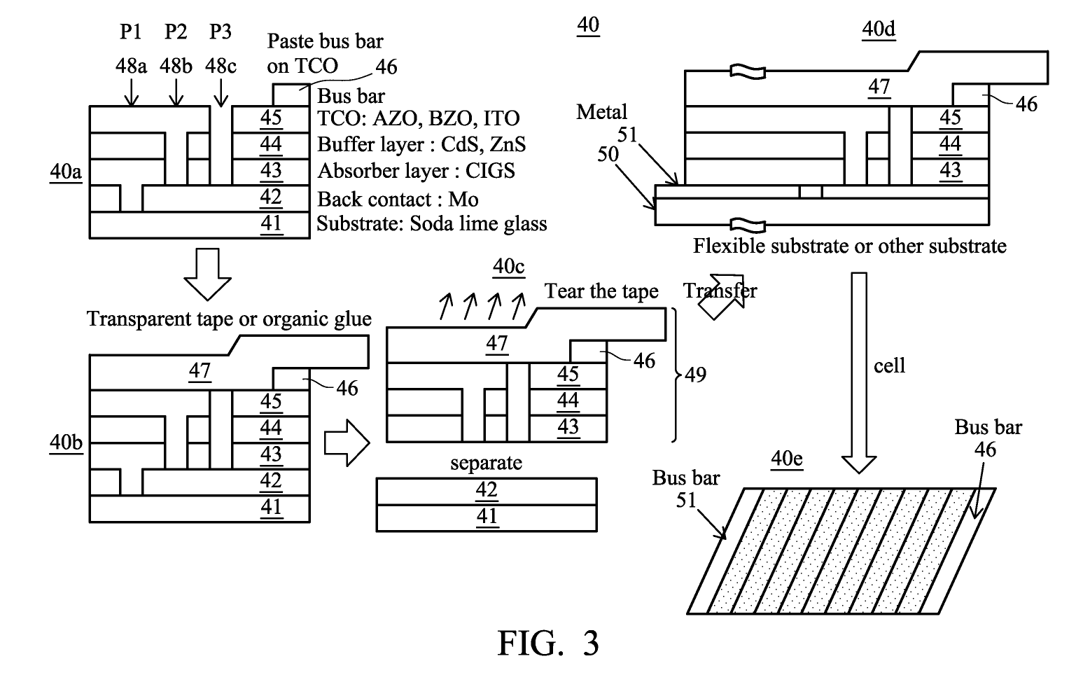

Referring to FIG. 3, another embodiment of a process 40 of manufacturing a solar cell includes at a first process 40a, a substrate 41, a back contact layer 42, an absorber layer 43 on the back contact layer 42, a buffer layer 44 on the absorber layer 43, and a front contact layer 45 above the buffer layer 44. In some embodiments, the substrate 41 is a glass substrate, such as soda lime glass. In some embodiments, the substrate 41 has a thickness in a range from 0.1 mm to 5 mm.

In some embodiments, the back contact 42 is formed of molybdenum (Mo) above which a CIGS absorber layer 43 can be formed. In some embodiments, the Mo back contact 42 is formed by sputtering. Other embodiments include other suitable back contact materials. such as Pt, Au, Ag, Ni, or Cu, instead of Mo. For example, in some embodiments, a back contact layer of copper or nickel is provided, above which a cadmium telluride (CdTe) absorber layer can be formed. Following formation of the back contact layer 42, the P1 scribe line 48a is formed in the back contact layer 42. The P1 scribe line 48a is to be filled with the absorber layer material. In some embodiments, the back contact 42 has a thickness from about 10 μm to about 300 μm.

The absorber 43, such as a p-type absorber 43 is formed on the back contact 42. In some embodiments, the absorber layer 43 is a chalcopyrite-based absorber layer comprising Cu(In,Ga)Se₂ (CIGS), having a thickness of about 1 micrometer or more. In some embodiments, the absorber layer 43 is sputtered using a CuGa sputter target (not shown) and an indium-based sputtering target (not shown). In some embodiments, the CuGa material is sputtered first to form one metal precursor layer and the indium-based material is next sputtered to form an indium-containing metal precursor layer on the CuGa metal precursor layer. In other embodiments, the CuGa material and indium-based material are sputtered simultaneously, or on an alternating basis.

In other embodiments, the absorber comprises different materials, such as CulnSe₂ (CIS), CuGaSe₂ (CGS), Cu(In,Ga)Se₂ (CIGS), Cu(In,Ga)(Se,S)₂ (CIGSS), CdTe and amorphous silicon. Other embodiments include still other absorber layer materials.

Other embodiments form the absorber layer by a different technique that provides suitable uniformity of composition. For example the Cu, In, Ga and Seₑ can be coevaporated and simultaneously delivered by chemical vapor deposition (CVD) followed by heating to a temperature in the range of 400° C. to 600° C. In other embodiments, the Cu, In and Ga are delivered first, and then the absorber layer is annealed in an Se atmosphere at a temperature in the range of 400° C. to 600° C.

In some embodiments, the absorber layer 43 has a thickness from about 0.3 μm to about 8 μm. In some embodiments, the buffer layer 44 can be one of the group consisting of CdS, ZnS, In₂S₃, In₂Se₃, and Zn₁₋ₓMgₓO, (e.g., ZnO). Other suitable buffer layer materials can be used. In some embodiments, the buffer layer 44 has a thickness from about 1 nm to about 500 nm.

The front contact layer 45 can be formed of any of the materials listed in Table 1, doped with any one of the dopants corresponding to each material in Table 1.

TABLE 1

| TCO material | Dopant |
|---|---|
| SnO₂ | Sb, F, As, Nb, Ta |
| ZnO | Al, Ga, B, In, Y, Sc, F, V, Si, Ge, Ti, Zr, Hf, Mg, As, H |
| In₂O₃ | Sn, Mo, Ta, W, Zr, F, Ge, Nb, Hf, Mg |
| CdO | In, Sn |
| Ta₂O | |
| GaInO₃ | Sn, Ge |
| CdSb₂O₃ | Y |
| ITO | Sn |

The completed solar cell includes an interconnect structure. The remainder of the area of the solar cell is the active cell area, which effectively absorbs photons. The figures are not to scale, and one of ordinary skill in the art understands that the active area is substantially larger than the interconnect structure.

The front contact layer 45 is provided over the entire solar cell area, (except where it is removed in the P3 scribe line (48c)). Following formation of the absorber layer 43 and the buffer layer 44, the P2 scribe line 48b is formed in the buffer layer 44 and the absorber layer 43. The P2 scribe line 48b is then filled with the front contact (or TCO) layer material. Following formation of the buffer layer 44 and the TCO layer 45, the P3 scribe line 48c is formed in the TCO layer 45, the buffer layer 44, and the absorber layer 43. As with the embodiment of FIG. 1, a metal bus bar 46 is pasted or adhered to the TCO layer 45 as shown. At process step 40b, a transparent tape or organic glue 47 is applied or placed on the TCO layer 45 and on the metal bar 46. The tape or glue 47 is used to extract, separate, delaminate or otherwise remove an extracted portion 49 from the substrate 41 and back contact layer 42 as shown in process step 40c. The extracted portion 49 includes the absorber layer 43, the buffer layer 44, the TCO layer 45, the metal bar 46 and the transparent tape or organic glue 47. The process of 40c is done at room temperatures without necessarily applying temperatures exceeding 500 degrees Celsius. If needed, some application of heat, electricity or pressure can be used in the separation or delamination process of 40c.

In a transfer process 40d, the extracted portion 49 is then transferred or pasted to another substrate such as a flexible substrate 50 which can optionally include a metal foil or conductive polymer layer 51. Between the transfer films or extracted portion 49 and the substrate 50, the addition of a conductive polymer layer or metal foil is used decrease the contact resistance and improve the adhesion between extracted portion 49 and the substrate 50. The substrate 50 can be made of other kinds of materials and can include metal foil or other flexible substrate coatings with conductive metal. With further edge deletions and placements of metal bars, a solar cell can be formed at 40e including a bus bar 51 and a bus bar 46.

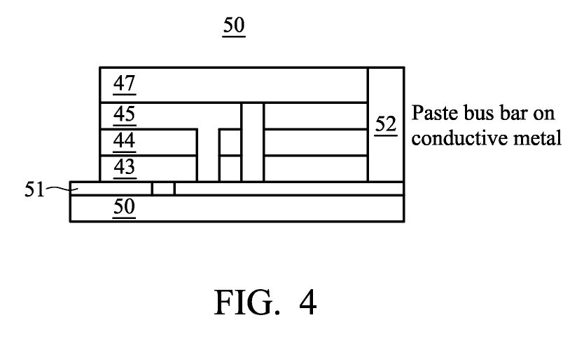

Referring to FIG. 4, a side view of a solar cell 50 similar to the solar cell of step 40d further includes a bus bar 52 that is pasted on the conductive layer 51 to form an appropriate top contact. Each solar cell has a respective interconnect structure. The interconnect structure comprises the plurality of scribe lines P1, P2, P3 (shown in FIGS. 3 and 4) that separate the active portions of adjacent cells.

In some embodiments, the P2 scribe line is filed with a high conductivity material comprising a metal or alloy. In some embodiments, the P2 scribe line is filed with a high conductivity material comprising aluminum, copper, or molybdenum. The higher conductivity material can be included in the P2 scribe line of any of the embodiments described above.

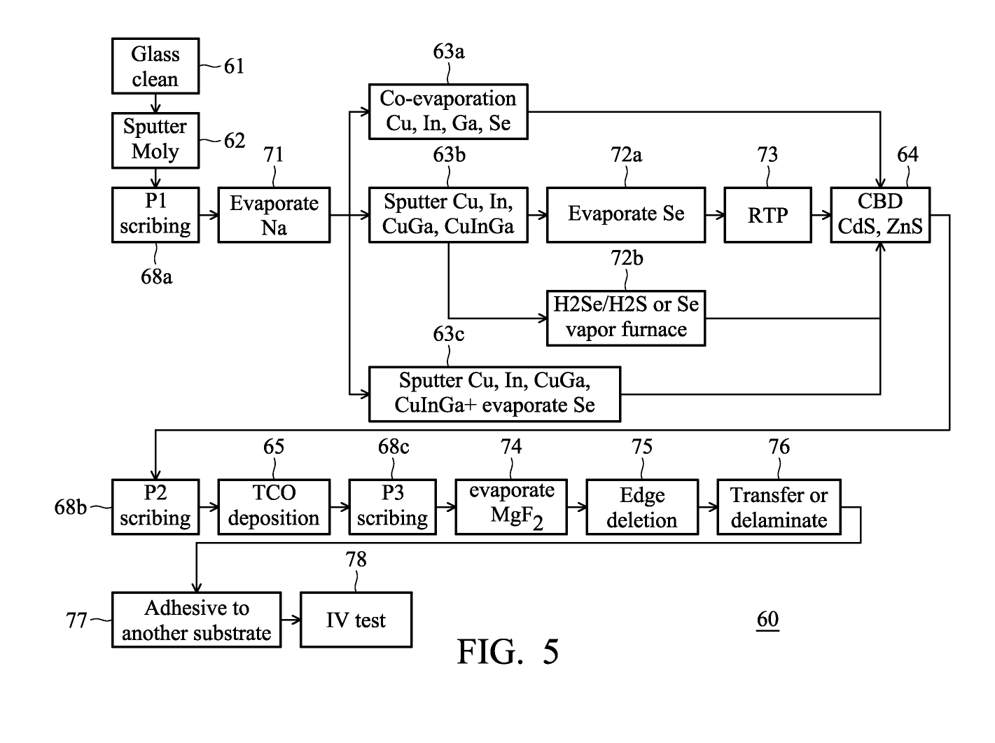

Referring to FIG. 5, an example of a flow chart of making a solar cell is shown in further detail. The process at step 61 includes providing a glass substrate. At step 62, a back contact layer is formed on the substrate by sputtering Mo or molybdenum. At step 68a, scribing of the P1 line can be done. At 71, sodium can be evaporated. At step 63, an absorber layer is formed on the back contact layer. In one alternative, 63a, provides for the co-evaporation of Cu, In, Ga, and Se. In another alternative, 63b, provides for the sputtering of Cu, In, CuGa, and CuInGa. In yet another alternative, 63c provides for the sputtering of Cu, In, CuGa, and CuInGa+ the evaporation of Se. If steps 63a or 63c are used, then the method continues by chemical bath deposition of cadmium sulfide or zinc sulfide at step 64. If step 63b is used, then the method can continue by evaporating Se at step 72a and then rapid thermal processing at step 73 before the chemical bath deposition step at 64. Alternatively, if step 63b is used, then a H2Se or H2S or Se vapor furnace is used at 72b before the chemical bath deposition step 64. After step 64, P2 scribing at step 68b can be done before TCO deposition at step 65. After TCO deposition, then P3 scribing can be done at 68c. At step 74, MgF2 is evaporated. At step 75, appropriate edge deletion before the transfer or delamination step 76. Step 76 separates an extracted portion that is then adhered to another substrate at step 77. Subsequently, the solar cell can be tested using an I-V test at step 78.

In some embodiments, a solar cell includes an absorber layer, a buffer layer on the absorber layer, a front contact layer, where a glass substrate, a back contact layer on the glass substrate, the absorber layer on the back contact layer, the buffer layer, and the front contact layer are manufactured as a first module at a temperature exceeding 500 degrees Celsius. The solar further includes an extracted portion from the first module where the extracted portion comprises the absorber layer, the buffer layer, and the front contact layer. The solar cell further includes a flexible substrate or other substrate, where the extracted portion is applied to the flexible substrate or other substrate.

In some embodiments, the extracted portion is applied to the flexible substrate or other substrate at a temperature below 500 degree Celsius. In other embodiments, the extracted portion is applied to a metal layer or a conductive polymer layer and the flexible substrate or other substrate.

In another embodiment, the flexible substrate or other substrate is a interconnect layer that interconnects the extracted portion to a second front contact layer of a second module comprising a second glass substrate, a second back contact layer, a second absorber layer, a second buffer layer, and the second front contact layer where the extracted portion and the second module form a tandem solar cell. The second module can be one of a silicon solar cell, a dye-sensitized solar cell, an organic solar cell, or a copper indium, gallium, selenium (CIGS) solar cell.

In some embodiments, a conductive bus can be applied to the front contact layer and a transparent tape or an organic glue or a transparent conductive tape can be placed on at least portions of a top of the front contact layer and the conductive bus.

In some embodiments, the glass substrate comprises soda lime glass, the back contact layer comprises molybdenum, the absorber layer comprises copper, indium, gallium, and selenium, the buffer layer comprises one of cadmium sulfide or zinc sulfide, and the front contact layer comprises one of aluminum-doped zinc oxide, boron-doped zinc oxide, or indium tin oxide.

In some embodiments, a transparent conductive tape or organic glue is used to separate the extracted portion from the glass substrate and the back contact layer.

In some embodiments, a first scribed portion exists through the back contact layer, a second scribed portion exists through the absorber layer, and a third scribed portion exists through the back contact layer, the absorber layer, and the front contact layer.

In some embodiments, the flexible substrate or the other substrate is a different shape from the glass substrate.

In yet another embodiment, a method of making a solar cell can include forming a back contact layer on a glass substrate, forming an absorber layer on the back contact layer, forming a buffer layer on the absorber layer, and forming a front contact layer above the buffer layer, the glass substrate, the back contact layer, the absorber layer, the buffer layer, and the front contact layer forming a first module. The method can further include extracting from the first module an extracted portion comprising the absorber layer, the buffer layer, and the front contact layer and applying the extracted portion above a flexible substrate or other substrate. In some embodiments, in the first module is manufactured at a temperature exceeding 500 degrees Celsius.

In some embodiments, the flexible substrate or other substrate is an interconnect layer connecting the extracted portion to a second module, where the method further includes forming a second back contact layer on a second glass substrate, forming an second absorber layer on the second back contact layer, forming a second buffer layer on the second absorber layer, forming a second front contact layer above the second buffer layer, wherein the second glass substrate, the second back contact layer, the second absorber layer, the second buffer layer, and the second front contact layer form the second module, and forming the interconnect layer between the extracted portion and the second contact layer of the second module. The extracting can include delaminating or tearing the extracted portion from the back contact layer and the glass substrate.

In one embodiment the method can further include forming transparent conductive tape or organic glue on the front contact layer.

In another embodiment, the method can further include scribing a first scribed portion through the back contact layer, scribing a second scribed portion through the absorber layer, and scribing a third scribed portion through the back contact layer, the absorber layer, and the front contact layer.

In yet another embodiment, a method of making a solar cell includes forming a back contact layer on a glass substrate by sputtering molybdenum on the glass substrate, forming an absorber layer on the back contact layer by sputtering or co-evaporating combination s of copper, indium, gallium, and selenium on the back contact layer, forming a buffer layer on the absorber layer by chemical bath deposition of cadmium sulfide or zinc sulfide on the absorber layer, and forming a front contact layer above the buffer layer, wherein the glass substrate, the back contact layer, the absorber layer, the buffer layer, and the front contact layer form a first module formed at temperatures exceeding 500 degrees Celsius. The method further includes transferring or delaminating from the first module an extracted portion comprising the absorber layer, the buffer layer, and the front contact layer and applying the extracted portion above a flexible substrate or other substrate.

Although the subject matter has been described in terms of exemplary embodiments, it is not limited thereto. Rather, the appended claims should be construed broadly, to include other variants and embodiments, which may be made by those skilled in the art.

What is claimed is:

1. A solar cell, comprising:
an absorber layer;
a buffer layer on the absorber layer;
a front contact layer, wherein a glass substrate, a back contact layer on the glass substrate, the absorber layer on the back contact layer, the buffer layer, and the front contact layer are manufactured as a first module at a temperature exceeding 500 degrees Celsius;
an extracted portion from the first module, the extracted portion comprising the absorber layer, the buffer layer, and the front contact layer; and
a flexible substrate or other substrate, wherein the extracted portion is applied to the flexible substrate or other substrate.

2. The solar cell of claim 1, wherein the extracted portion is applied to the flexible substrate or other substrate at a temperature below 500 degree Celsius.

3. The solar cell of claim 1, wherein the extracted portion is applied to a metal layer and the flexible substrate or other substrate.

4. The solar cell of claim 1, wherein the extracted portion is applied to a conductive polymer layer and the flexible substrate or other substrate.

5. The solar cell of claim 1, wherein the flexible substrate or other substrate is a interconnect layer that interconnects the extracted portion to a second front contact layer of a second module comprising a second glass substrate, a second back contact layer, a second absorber layer, a second buffer layer, and the second front contact layer.

6. The solar cell of claim 5, wherein the extracted portion and the second module form a tandem solar cell.

7. The solar cell of claim 6, wherein the second module is one of a silicon solar cell, a dye-sensitized solar cell, an organic solar cell, or a copper indium, gallium, selenium (CIGS) solar cell.

8. The solar cell of claim 1, comprising a conductive bus applied to the front contact layer and a transparent tape or an organic glue or a transparent conductive tape placed on at least portions of a top of the front contact layer and the conductive bus.

9. The solar cell of claim 1, wherein the absorber layer comprises copper, indium, gallium, and selenium.

10. The solar cell of claim 1, wherein the glass substrate comprises soda lime glass, the back contact layer comprises molybdenum, the absorber layer comprises copper, indium, gallium, and selenium, the buffer layer comprises one of cadmium sulfide or zinc sulfide, and the front contact layer comprises one of aluminum-doped zinc oxide, boron-doped zinc oxide, or indium tin oxide.

11. The solar cell of claim 1, comprising a transparent conductive tape or organic glue used to separate the extracted portion from the glass substrate and the back contact layer.

12. The solar cell of claim 1, comprising a first scribed portion through the back contact layer, a second scribed portion through the absorber layer, and a third scribed portion through the back contact layer, the absorber layer, and the front contact layer.

13. The solar cell of claim 1, wherein the flexible substrate or the other substrate is a different shape from the glass substrate.

14. A method of making a solar cell, comprising
forming a back contact layer on a glass substrate;
forming an absorber layer on the back contact layer;
forming a buffer layer on the absorber layer;
forming a front contact layer above the buffer layer, the glass substrate, the back contact layer, the absorber layer, the buffer layer, and the front contact layer forming a first module;
extracting from the first module an extracted portion comprising the absorber layer, the buffer layer, and the front contact layer; and
applying the extracted portion above a flexible substrate or other substrate.

15. The solar cell of claim 14, wherein the first module is manufactured at a temperature exceeding 500 degrees Celsius.

16. A method of making a solar cell of claim 14, wherein the flexible substrate or other substrate is an interconnect layer connecting the extracted portion to a second module, and wherein the method further comprises:
forming a second back contact layer on a second glass substrate;
forming an second absorber layer on the second back contact layer;
forming a second buffer layer on the second absorber layer;
forming a second front contact layer above the second buffer layer, wherein the second glass substrate, the second back contact layer, the second absorber layer, the second buffer layer, and the second front contact layer form the second module; and
forming the interconnect layer between the extracted portion and the second contact layer of the second module.

17. The method of claim 14, wherein the extracting comprises delaminating or tearing the extracted portion from the back contact layer and the glass substrate.

18. The method of claim 14, further comprising forming transparent conductive tape or organic glue on the front contact layer.

19. The method of claim 14, further comprising scribing a first scribed portion through the back contact layer, scribing a second scribed portion through the absorber layer, and scribing a third scribed portion through the back contact layer, the absorber layer, and the front contact layer.

20. A method of making a solar cell, comprising
forming a back contact layer on a glass substrate by sputtering molybdenum on the glass substrate;
forming an absorber layer on the back contact layer by sputtering or co-evaporating combination s of copper, indium, gallium, and selenium on the back contact layer;
forming a buffer layer on the absorber layer by chemical bath deposition of cadmium sulfide or zinc sulfide on the absorber layer;
forming a front contact layer above the buffer layer, wherein the glass substrate, the back contact layer, the absorber layer, the buffer layer, and the front contact layer form a first module formed at temperatures exceeding 500 degrees Celsius;
transferring or delaminating from the first module an extracted portion comprising the absorber layer, the buffer layer, and the front contact layer; and
applying the extracted portion above a flexible substrate or other substrate.
